(19) United States
(12) Patent Application Publication
(10) Pub. No.: US 2014/0299175 A1
(43) Pub. Date: Oct. 9, 2014

(54) RIGID OR FLEXIBLE SOLAR COLLECTOR WITH AN IMAGE DISPLAYED ON THE SURFACE AND METHODS FOR PRODUCING SAME

(71) Applicant: SUNPARTNER TECHNOLOGIES, Aix en Provence (FR)

(72) Inventor: Joël Gilbert, Eguilles (FR)

(21) Appl. No.: 14/352,926

(22) PCT Filed: Oct. 16, 2012
(86) PCT No.: PCT/FR2012/000418

§ 371 Date: Apr. 18, 2014

(30) Foreign Application Priority Data
Oct. 18, 2011 (FR) 11/03192

(51) Int. Cl. H01L 31/052; H01L 31/18; F24J 2/08

(52) U.S. Cl. CPC H01L 31/0524; F24J 2/08; H01L 31/18
USPC 136/246; 126/700; 29/890.033

(57) ABSTRACT

A device with a collector for collecting light energy from a light source includes a transparent plate between the light source and the collector, whereof a first face is structured by an array of lenses separated by slots, while the second face contains areas of pixels, and transparent areas. An observer can view an image on the surface of the screen, even though the screen is transparent to solar radiation. This solar radiation reaches a solar collector behind the plate. The slots are provided in the thickness of the plate and have the effect of making the screen flexible and rollable about an axis. These slots also have the optical property of increasing the angles of view of the image. This invention is particularly suitable for the visual integration of solar collectors into the environment, generally on any imaged media, including electronic images, and on any planar or non-planar surfaces.

The present invention relates to thermal and/or photovoltaic solar collectors and, more particularly, to the visual integration of these collectors by making it possible to display an image on their surface.

The discreet visual integration of the solar collectors is particularly useful in objects whose main function is to serve as a screen, at least partially, to solar rays, such as, for example, in the case of blinds, sun shades, parasols, awnings and the like.

However, a good visual and functional integration of solar collectors can also be useful in a wider range of supports, such as buildings, roofs, walls, tiles, glazing, transportation vehicles, including boats and airplanes, advertising panels and billboards, electronic screens, clothing, and, generally, on any planar or non-planar support.

In this respect, two technical problems arise.

A first problem stems from the generally dark appearance of the known solar collectors, which is prejudicial to a good visual integration of these collectors on supports of a different color to that of the collectors. In practice, most of the solar collectors are of a uniform and dark color because they are made up of materials which are themselves of uniform and dark color such as crystalline or amorphous silicon for the photovoltaic collectors, and such as copper or aluminum covered with titanium or a black absorbent for the thermal solar collectors.

Some photovoltaic cells are, however, known from the prior art which use materials that are transparent to visible light, which makes it possible to display a colored image through the cells. However, these cells convert into electricity only a portion of the solar spectrum such as the infrared rays or the ultraviolet rays, so that the electrical performance levels thereof are ultimately fairly low. The various known solar collectors do not therefore make it possible to display a colored image through their surface while capturing all of the solar radiation, which would however facilitate the visual integration of these solar collectors in our environment while keeping their performance levels significantly high.

A few devices are also known that make it possible to display an image on their surface while capturing the solar radiation. These devices use a network of rectilinear microlenses associated with image bands and with bands of solar collectors in order to be able to display an image on the surface of the solar panel from certain angles of observation whereas, from other angles of incidence, the light illuminates the bands of solar collectors. However, these devices have a drawback which is that the solar radiation capture angles and the image display angles are limited to a relatively small angular range, beyond which the observer will see the solar collector instead of the image and the solar rays will touch the image instead of the solar collector.

Another problem stems from the absence of flexibility of most of the known solar collectors, which greatly limits their use to an application on substantially planar supports, whereas the existence of flexible solar collectors would make it possible to increase the potential applications of this technology.

It will be well understood that simultaneously resolving the two issues mentioned would make it possible both to envisage solar collector applications on non-planar surfaces, and to give these solar collectors a much more subtle appearance making it possible to visually integrate them well in the various supports considered, with no loss of performance.

The aim of the present invention is consequently to resolve these two issues and to propose, on the one hand, a solar collector that is substantially transparent, from a visual point of view, and, on the other hand, to propose a solar collector that is flexible and can be adapted to non-planar supports.

Obviously, in its most sophisticated version, the aim of the invention is to resolve both issues simultaneously and to propose a solar collector that is both substantially transparent to visible light, and flexible enough on its primary surface to be easily applied to non-planar supports.

To this end, the present invention describes an optical device which increases the total angular range for displaying the image and for capturing the solar rays to 180°. Furthermore, the present invention will make it possible to make the lenticular surface flexible even with significant lens thicknesses.

Consequently, the subject of the invention is a device comprising at least one collector of light energy originating from a light source, characterized in that it also comprises a transparent plate positioned between the light source and said collector, and a first face of which is structured by a network of lenses separated by slots, the distance between the bottom of the slots formed on one face of the transparent plate and the opposite face of the transparent plate being such that it allows the transparent plate to flex at this point, whereas the second face of the transparent plate contains areas of pixels of an image, and areas of transparency.

According to the embodiments retained, said lenses are convex or concave, and of symmetrical or asymmetrical form.

The transparent plate is, for example, made of mineral glass, of organic glass, of a polymer such as PET (polyethylene terephthalate), PMMA (polymethylmethacrylate), or polycarbonate, or even silicone.

The slots are preferably formed in the front face of the plate directly exposed to the light source, and they are preferably rectilinear and perpendicular to the plane of the plate. These slots are, for example, parallel to one another (in the unwound position of the device) and the distances which separate them are all identical.

The depth of the slots is such that a thickness of material is left between the bottom of the slot and the rear face of the plate. This thickness of material is small enough to allow a deformation at this point but without resulting in rupture, enabling the device to be wound.

Each patch of the transparent plate delimited by the line of the slots has, on the rear face of the plate, a corresponding pixelized area and a corresponding area of transparency.

Behind the plate, on the side of the rear face, a light energy collector, typically a solar collector, is positioned. The solar collector can be of all types, for example thermal and/or photovoltaic or chemical. If it is photovoltaic, it can be made of crystalline or amorphous silicon or of thin or organic layers. If it is thermal, it can be made of copper, of aluminum, of PVC (polyvinylchloride), passed through by a heat transfer liquid or by a gas such as air. The solar collector itself can be rigid or else flexible, even along just one axis. Obviously, the solar collector will be connected to an electrical or hydraulic circuit in order to enable it to operate correctly and to allow for the energy generated to be recovered.

The pixelized areas and the areas of transparency of the transparent plate have a form and a size, and are positioned relative to the slots, such that, from certain angles of observation, an observer looking at the front face will see only the pixelized areas which will be combined together to enable an image to be displayed on the entire surface of the plate, whereas, from other angles, the direct or indirect solar radiation will be refracted at the surface of the plate, will pass through the areas of transparency and then activate the solar collector which is located behind the plate.

Preferably, the opposing faces inside each slot are sufficiently polished for these surfaces to have the property of reflecting certain light rays which come from inside the plate. This optical reflection occurs as a result of the difference in refractive index between the transparent material of the plate and the air which is contained in the slots. A portion of the rays from a light source, in particular from the sun, will thus be reflected on the walls of the slots and will pass through the areas of transparency, whereas other solar rays will pass directly through the areas of transparency without being reflected at the surface of the slots.

The quantity of light which will pass through the areas of transparency and which will reach the solar collector will then be greater than the quantity of light which would have passed through the areas of transparency if the slots did not exist, which will cause the energy production yield of the device to be increased.

The mirror-type optical reflection on the walls of the slots acts also for the outgoing rays from the pixelized areas, which enables an observer to view all the pixelized areas, therefore an entire image, from much greater angles than if the slots did not exist. The result thereof is that the visual integration of the device on a support will be effective over a wider angular range than it would without the slots.

Also, the presence of slots induces the property rendering the plate capable of being bent along these slots and even, if the slots are rectilinear and parallel, of winding around a cylinder with an axis of rotation that is parallel to the longitudinal axis of the slots. By virtue of these slots, the rigidity of the plate is therefore no longer proportional to its thickness, which means that greater thicknesses, for example one or more millimeters, can be used for the plate while having good flexibility. The thickness of the plate then makes it possible to have pixelized areas with dimensions that will be able to be of the same order of magnitude as the thickness of the plate which will facilitate their manufacture and the accuracy of their positioning.

According to different embodiments, the slots have their aperture either on the side of the front face provided with lenses and exposed to the light source, or on the side of the rear face. The side of the plate where the aperture of the slots is located determines the direction of the flexing or of the winding of this plate, namely that this flexing or winding will be done about an axis which will be on the side opposite the aperture of the slots. The slots are preferably perpendicular to the plane in which the plate is inscribed in the absence of flexing, but, in order to control the viewing angles and the angles of transparency, the slots may be inclined relative to the perpendicular to the plane of the plate by a non-zero angle.

In a particular embodiment, the front face of the transparent plate will have undergone an antiglare treatment.

In another embodiment, the front plate is covered by another plate or a transparent film, rigid or flexible, so as to protect the slots against the ingress of dirt. This protection plate will also be able to be treated on its outer face against glare.

In another embodiment which is not represented, the solar collectors cover only the areas of transparency and not the pixelized areas. In this case, the solar collectors, such as, for example, thin film photovoltaic cells, will be able to have the same form and the same size as the areas of transparency, and alternate therewith.

In another embodiment which is not represented, the pixelized areas are made up of electronic pixels generated by backlit components such as LCDs (Liquid Crystal Displays), or light-emitting components such as LEDs (Light-Emitting Diodes) or OLEDs (Organic Light Emitting Diodes), or even reflecting pixels of colored filter type on a mirror surface, or even pixels whose color is determined by an optical diffraction grating effect, or whose colored reflection is determined by a light interference effect.

In all these cases, the support for the electronic pixels will be able to be rigid or else flexible. The supports for electronic pixels, although not illustrated, will contain all the electrical connections necessary to their operation.

In another particular embodiment illustrated in FIG. 5, the solar collectors, preferably photovoltaic cells, are positioned on one of the two faces of the slots and the pixelized areas cover all or part of the rear face of the plate. The advantage of this arrangement is that an observer standing in front of a vertical solar screen implementing this invention will see only the image and will not see the solar collectors at all, even within a significant angular range between 0° corresponding to the perpendicular to the plane of the plate, and 90° corresponding to vision close to the vertical.

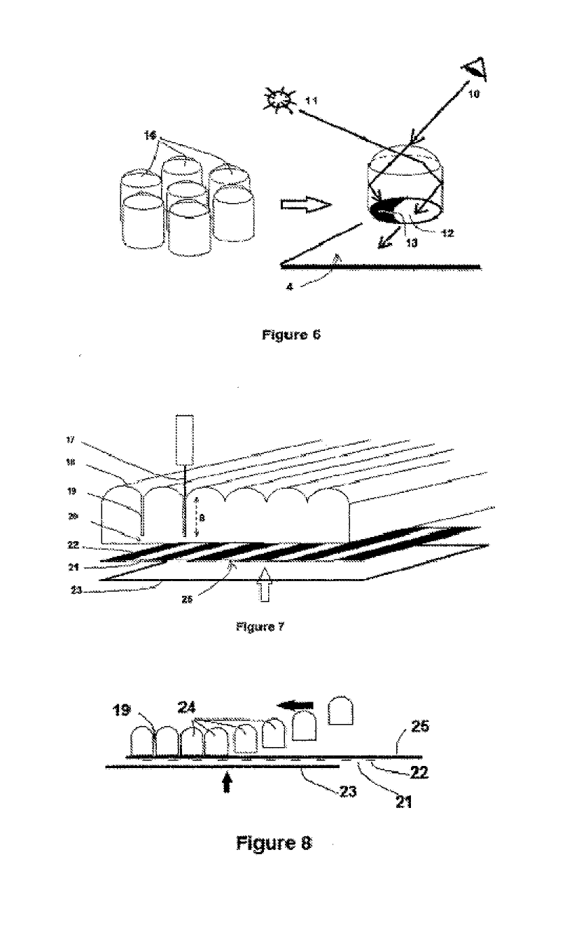

In another particular embodiment illustrated in FIG. 6, the slots delimit (or are delimited by) cylindrical forms whose longitudinal axes are perpendicular to the plate. The base of the cylindrical forms can be circular, or polygonal, hexagonal for example, and contains a pixelized area and/or an area of transparency, with, behind the plate, a thermal or photovoltaic solar collector. For certain positions relative to the device, an observer will then see only the pixelized areas, and therefore, globally, an image, whereas solar rays, direct or after reflection on the walls of the cylinders, will reach the solar collector after having passed through the areas of transparency. In order to render the solar screen even more flexible, the cylindrical forms concerned will be able to be miniaturized and have the dimensions and the characteristics of optical fibers, such as, for example, diameters less than 500 microns.

In another embodiment which is not represented, the pixelized areas are not covered by the solar collectors and are wholly or partly transparent to the light, which will enable an observer positioned behind the plate to receive at least a portion of the light, in particular solar, received by the front of the plate.

In another embodiment, the air spaces of the slots completely separate the different parts of the plate from one another, and a transparent film is then glued over the entire rear face of the plate in order to hold these parts in position relative to one another. This transparent film will be able to be rigid or flexible, and the latter case will then make it possible to fold the plate at the air spaces and thus obtain the general flexibility of the plate.

The invention is mainly applicable in the case where the light source is the sun, and said light energy collector is then a solar collector of thermal, photovoltaic or chemical type.

Another subject of the invention is a method for manufacturing a device as above, characterized in that it comprises steps consisting in:
procuring a transparent plate structured on one of its faces by a network of lenses, and comprising, on the other face, an image formed by areas of pixels, spaced apart by bands of transparency;
depositing a layer of photovoltaic amorphous silicon on the image face;
producing, in the face provided with lenses, between two consecutive lenses, slots with a depth that leaves a thickness of material remaining capable of ensuring that the transparent plate can flex.

According to another variant, the method for manufacturing the device comprises steps consisting in:
procuring transparent rods, one of the faces of which is in the form of a lens, and a transparent film, on one of the faces of which is provided with image areas spaced apart by bands of transparency;
gluing the face said transparent rods together side by side on said transparent film in such a way that each rod is glued by its face opposite to that which is in the form of a lens, and in such a way as to leave, between each of said rods, an air space with parallel faces, said rods having a width such that they cover an image band and a band of transparency;
procuring one or more solar collectors and positioning them on the face of the transparent plate opposite that which bears the slots, so that said solar collectors have their active faces facing the areas of transparency.

According to another variant, the manufacturing method comprises steps consisting in procuring a transparent plate having a planar face and a face provided with a network of lenses, the planar face being configured as above with areas of transparency and pixelized areas, then forming, in one or both of the faces, a network of slots by molding, thermoforming or extrusion.

The invention will be better understood from its detailed description in relation to the figures, in which:

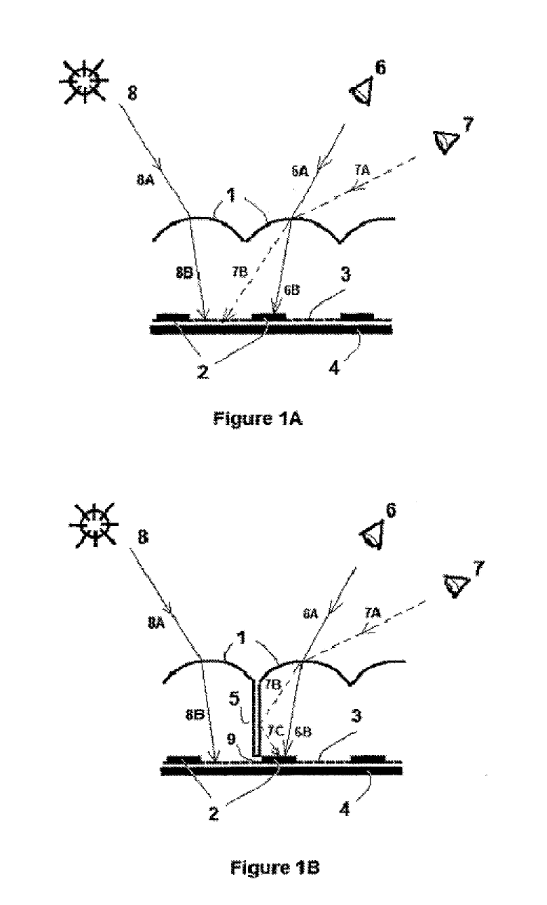

FIG. 1A is a view in elevation and in cross section of a lenticular solar collector element according to the prior art;

FIG. 1B is a view in elevation and in cross section of a solar collector element according to the invention;

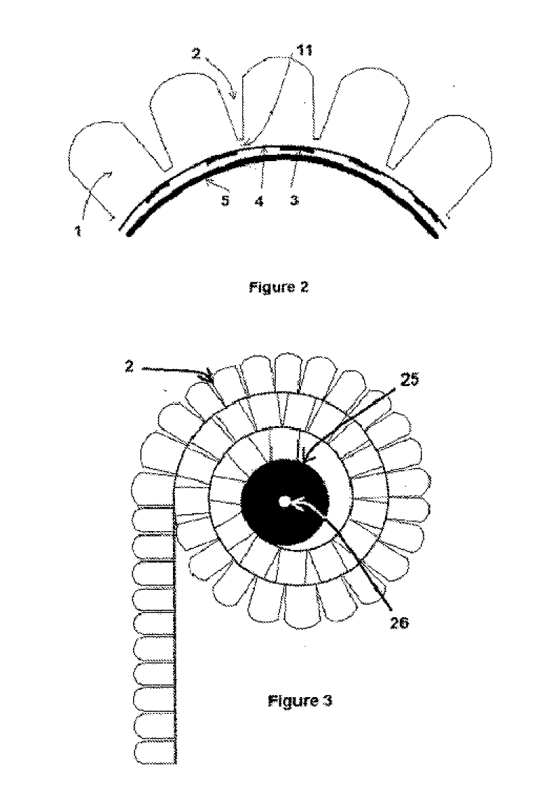

FIG. 2 is a view in elevation and in cross section of the solar collector of FIG. 1B, in a bent position;

FIG. 3 is a view in cross section of a set of solar collectors according to FIGS. 1B and 2, wound around an axis;

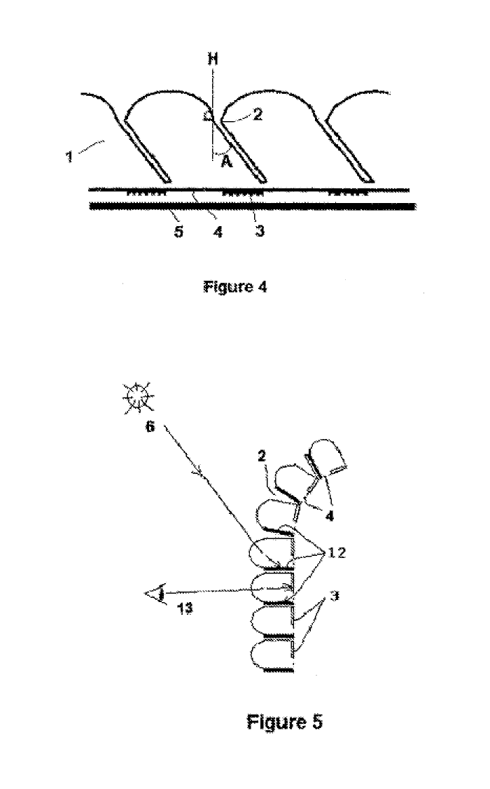

FIG. 4 is a view in elevation and in cross section of a first variant solar collector according to FIG. 1B;

FIG. 5 is a view in elevation and in cross section of a second variant solar collector according to FIG. 1B;

FIG. 6 is a view in perspective showing another variant embodiment of a solar collector according to the invention;

FIG. 7 is a view in perspective schematically showing the steps of producing a solar collector according to FIG. 1B;

FIG. 8 is a view schematically showing the steps of a variant method for producing the solar collector according to the invention.

The figures are not to scale, the relative thickness of the device being exaggerated in order to give a better appreciation of the structure.

Reference is made to FIG. 1 which corresponds to a known solar collector according to the patent WO/2007/085721. It comprises a transparent plate 1 that has a front face is exposed to the sun 8 and provided with a network of lenses 10. The rear face 1b is provided with alternating areas of transparency 4 and areas of pixels 3 of an image. Behind the areas 3, 4 there is a solar collector 5. The result of this is that, from certain angles of incidence, an incident solar ray 8A, 8B will pass through the transparent plate 1 and the areas of transparency 4 to strike the solar collector 5. An observer standing at 6 will see the pixels 3 of the image but will not see the solar collector 5 placed behind the areas of transparency, this collector being visible only from other angles, as represented by 7.

The known solar collector according to FIG. 1B in practice has a drawback which is that the solar radiation capture angles and the image display angles are limited to a total angular range of approximately 55 degrees, which limits the possible inclination of the collectors relative to the travel of the sun and relative to the observer. Beyond this angular range of 55 degrees, the observer will see the solar collector 5 instead of the image and the solar rays will touch the image instead of the solar collector.

Another problem with the solar collector according to FIG. 1A lies in its absence of flexibility, which greatly limits its use to an application on substantially planar supports, whereas the existence of flexible solar collectors would make it possible to multiply the potential applications of this technology.

Reference is made to FIG. 1B, which is a schematic diagram in elevation and in cross section of the various elements of the solar collector device according to the invention and capable of resolving the problems mentioned.

A transparent plate 1 made of glass or of organic glass has its front face is provided with a network of lenses 10, and its rear face 1b planar. The front face is is structured by a series of slots 2 separating two consecutive lenses, and whose two faces are planar and polished. In the example illustrated, these slots 2 are substantially perpendicular to the plane of the rear face 1b of the transparent plate 1, and these slots 2 can preferably be rectilinear and parallel to one another. “Front face is of the transparent plate 1” should be understood to mean the face which directly faces an observer and which directly receives the light radiation from a light source, in particular the sun 8 as represented.

The depth 18 of the slots 2 is preferably less than the thickness of the plate 1 so as to leave a thickness of material 11 remaining between the bottom of each slot 2 and the rear face 1b of the plate, this thickness of material 11 being small enough to allow for a certain flexing of the plate without breaking it.

On the rear face 1b of the plate 1, the surface delimited by two consecutive slots 2 comprises an area of transparency 4 and an area of pixels 3, also called pixelized area. When the slots 2 are rectilinear and parallel to one another, these two respective areas 4, 3 can preferentially be bands of transparency and image bands parallel to the longitudinal axis of the slots.

Through the application of the principles of light propagation, from certain angles, the incident light rays 8A, 8B will be refracted on the front face is of the plate 1, and then will reach the areas of transparency 4 behind the plate before reaching the solar collector 5, whereas, from other angles, an observer 6 will be able to see according to the optical path 6A, 6B the pixels 3 through the plate.

The light rays 9 from inside the transparent plate 1 which touch any one of the faces of the slots 2 are then reflected at the surface of these slots, as by a mirror, provided that the angles of incidence of these rays relative to the perpendicular to these faces are greater than a limit value that is a function of the refractive index of the transparent material forming the plate.

In the embodiment represented in FIG. 1B, the rear face 1b of the transparent plate 1 is totally covered by a solar collector 5 which therefore also covers the pixelized areas 3 of the image.

In another particular embodiment which is not represented, provision can be made for the solar collectors 5 to cover only the areas of transparency 4 of the plate 1, and not its image areas.

Depending on their angle of incidence, some solar rays 8 will pass through the areas of transparency 4 and touch the solar collector 5 placed behind the areas of transparency 4.

The solar collector or collectors 5 can be of all kinds, thermal or photovoltaic, rigid or flexible.

In order to define values for the angles of observation of the image areas 3 and for the angles where the transparency is observed, it will be possible to vary the distance between the consecutive slots 2, as well as their thickness 18. This refinement will be easily within the scope of a person skilled in the art according to each precise given application.

It will be noted that, in the interests of simplifying the description, the electrical or thermal devices associated with the solar collectors to ensure the collection and the redistribution of the electrical or thermal energy are not illustrated, since they are well known to those skilled in the art and do not form part of the invention proper.

The image areas 3 are typically pixels which emit colored light. This light can be light from the ambient light which is reflected on colored supports, such as printed or painted paper or film, mirror-type reflecting supports covered with colored filters or whose color is determined by an optical diffracting grating effect, or even whose colored reflection is determined by a light interference effect. This light can also be light from an electronic light source (such as LEDs, OLEDs or LCDs), provided with backlighting. The electrical power supply for these lighting devices is not illustrated.

FIG. 2 illustrates the device of FIG. 1B in a flexed position. During this flexing, the slots 2 whose walls were parallel in FIG. 1, now spread apart from one another to form an aperture angle which is all the greater when the flexing is great. The photovoltaic film of the solar collector 5 is itself flexible in this example, in order for its surface to remain close to the rear face of the plate.

FIG. 3 illustrates the device according to the invention in a position of winding around an axis or a cylinder. The solar screen device according to the invention is wound around a cylinder 25 which can rotate about its longitudinal axis 26. In this example, the aperture of the slots 2 is oriented toward the outside of the winding, and the longitudinal axis of the slots is parallel to the winding axis 26.

It can clearly be seen that, in this arrangement, it is possible for example to wind an image 3 combined with photovoltaic cells forming a solar collector 5, such that the photovoltaic production surface remains flexible and windable, while being masked from certain observation angles because of the slots 2. This ultimately makes it possible to have a windable photovoltaic surface showing an image 3, while masking the photovoltaic cells from most of the useful viewing angles.

FIG. 4 illustrates the device according to the invention in a particular embodiment where the slots 2 are inclined relative to the perpendicular to the surface of the transparent plate 1. The plate 1 is then structured on its front face is by slots 2 whose walls are inclined by an angle (A) relative to the perpendicular to the surface of the plate. The rear face 1b of the plate 1 contains, again, as in the embodiment according to FIG. 1B, alternating image areas 3 and areas of transparency 4 between the slots 2. A solar collector 5, for example photovoltaic, is positioned on the rear of the plate and entirely covers its surface.

FIG. 5 schematically represents a variant embodiment of the device according to the invention, in which the surfaces of solar collectors 5 are positioned no longer on the rear of the transparent plate, but directly on a face of each slot 2.

This positioning is particularly well suited to a solar screen positioned vertically. The rear face of the transparent plate 1 still comprises, between the slots 2, image areas 3 and areas of transparency 4.

Thus, an observer 13 placed facing the solar screen will see, through transparency, the image areas 3 of the plate 1. He or she will also see a possible support positioned behind the plate, through the areas of transparency 4. However, the solar collectors 5, which are positioned or glued here onto the bottom wall of the slots 2, will be almost invisible to the observer 13, in as much as these slots are substantially in the extension of his or her viewing axis.

By contrast, the solar rays 8 or the ambient light which comes from above are refracted at the surface of the transparent plate 1 and reach the solar collectors 5 situated on the slots and which are, in this example, in a horizontal position.

There is therefore, in this arrangement, in the deployed position of the solar screen, a production of electrical or thermal energy by the solar collectors 5, whereas these solar collectors remain invisible to the observer 13 who sees only the image 3. Furthermore, the solar screen represented offers a possibility of flexing or winding around an axis parallel to the longitudinal axis of the slots 2.

FIG. 6 represents a variant of the device according to the invention when the slots 2 are no longer delimited by planar faces, but by cylindrical forms 14. The transparent plate 1 is then structured on its front face is by slots or interstices whose walls are non-planar and delimit, for example, outlines which take the form of circles. The result is a juxtaposition of cylinders 14 whose longitudinal axis is perpendicular to the transparent plate 1, and whose height is slightly less than the thickness of said plate.

At the base of each cylinder 14, there are positioned an area of transparency 16 and an area of pixels 15. A portion of the light entering into each cylinder 14 is directed towards the area of transparency 16 and reaches the solar collector 5 situated behind it, whereas an observer, from certain viewing angles, will see only the pixels 15, and therefore, globally, an image.

Ultimately, from certain angles of incidence, the incident light passing through the areas of transparency 16 will reach the solar collector 5 and therefore produce energy, whereas an observer observing the structure from other angles will not be able to see the areas of transparency 16 and the solar collector 5 which is located behind, but will see only the areas of pixels 15 and therefore an image distinct from the solar collector.

Furthermore, depending on the flexibility chosen for the solar collector 5 and its support, it will be possible to confer a certain flexibility on the device and adapt it to non-planar supports.

Reference is now made to FIG. 7 which represents the principle of a method for manufacturing a device according to the invention.

According to a variant of this method, a laser beam is used to produce slots 2 in the transparent plate 1. The front face is of a transparent plate 1 is subjected to a laser beam 17 so as to create slots 2 therein, with a depth 18 which is less than or equal to the thickness of the plate 1.

The slots 2 are preferably rectilinear and perpendicular to the surface of the plate 1. The distance 20 between the bottom of the slots 2 and the rear face 1b of the plate is small enough to allow for flexing at this point without breaking. Between each slot and the rear surface of the plate, there are an area of pixels 3 and an area of transparency 4. If the slots 2 are rectilinear, the image areas 3 and the areas of transparency 4 will preferably also be rectilinear and configured in the form of bands.

A first variant of the manufacturing method consists in printing the areas of pixels 3 on a transparent film 25 and in gluing this film to the back of the plate 1, making the areas of pixels 3 correspond with the areas delimited by two consecutive slots 2. This film 25 will also advantageously be able to be used to hold the various parts in place, particularly in an embodiment in which the depth 18 of the slots is equal to the thickness of the transparent plate 1. The solar collector 5 which, in this nonlimiting example, is planar and covers all of the plate, is positioned or glued behind the plate 1.

FIG. 8 represents the principle of a variant method for manufacturing the device according to the invention. It consists, for producing the transparent plate 1 and the slots 2, in juxtaposing a series of transparent rods 24, which are glued onto a transparent film 25 acting as support. The section of the transparent rods 24 is, for example, square, except with respect to their front face which is in the form of a lens.

The rods 24 are juxtaposed side by side, leaving a film of air between two adjacent rods, thus producing slots 2 as explained previously, the rods 24 being glued by their planar rear face, in such a way that the lenticular faces are located on the front face is of the transparent plate 1.

In order to ensure the flexibility of the device, the transparent film 25 will itself be able to be flexible. It may have been printed, in advance, with rectilinear image bands 3 parallel to the longitudinal axis of the rods. The width of the image bands 3 will be, for example, half of the width of the rods 24.

Each image band 3 is positioned facing a rod 24. Bands of transparency 4 appear between two consecutive image bands 3. A solar collector 5 is procured and positioned on the rear of this device. This solar collector 5 will have its active face facing the rods 24. The solar collector 5 will be able to be glued to the structure, or else separated by an air space if it is a thermal collector.

There now follows a description of the dimensioning and the construction of an exemplary physical embodiment of a solar panel constructed and produced according to the invention.

A transparent flexible film of polyester measuring 30 cm by 70 cm and 0.1 mm thick is printed on one of its faces with bands of pixels 1 mm wide which are spaced apart by bands of transparency 1 mm wide.

The other face of the film is self-adhesive. The bands of pixels are predominantly orange colored. 35 transparent rods made of PMMA 70 cm long with each side measuring 2 mm, except with respect to the front face in the form of a lens, are procured. These rods are then positioned alongside one another on the printed film on the side of its self-adhesive face so that the face of the rods which is glued to the film corresponds to the face opposite the lenticular face and completely covers a band of pixels and a band of transparency.

The film onto which the 35 rods have been glued is mechanically fixed to the surface of a photovoltaic solar collector of the same dimensions as said film and such that said film is in contact with the solar collector.

The solar collector is then positioned on the orange tiles of a south-facing roof, or else in place of the tiles that it covers, such that the longitudinal axis of the rods is horizontal and such that the image bands are toward the top of the roof.

An observer looking at the solar panel on the roof will see on the surface of said panel only an orange color identical to those of the roof tiles, whereas the solar radiation will pass clearly through the plate and will activate the photovoltaic solar collector.

This configuration is only a simplified example of the manufacture and visual integration of a black solar panel on an orange roof which uses the method that is the subject of the invention.

The repetition of the above process applied to all the roof, and in place of the original tiles, is possible provided that the rectangular solar panel is equipped with a system which makes it possible, on the one hand, to ensure the seal-tightness between the panels, which may be the case for example if the panels partially overlap one another, and, on the other hand, which is equipped with a connection system for leading the electrical or thermal power generated by the solar panel.

In another non-limiting exemplary embodiment, a plate of PMMA 100 cm wide by 150 cm high and 1 mm thick is sourced, onto which is glued, with a transparent glue, a flexible photovoltaic film 0.5 mm thick, with the same width and height dimensions as the plate and on which have been printed white colored image bands, 0.5 mm wide, spaced apart from one another by bands of transparency of the same widths.

The printing is done with UV inks and the image bands and the bands of transparency are parallel to the width of the plate. Then, the unglued face of said plate is swept by a laser beam so as to create rectilinear slots parallel to the image bands, these slots being positioned above a joint between image band and band of transparency, and are spaced apart from one another by 1 mm such that the space between two slots precisely includes an image band and a band of transparency. The depth of the slots is 1 mm.

The plate thus structured by the slots becomes flexible and it can be wound around a rigid, hollow metal tube, 5 cm in diameter, and positioned parallel to the slots. The whole constitutes the essential part of a windable photovoltaic blind. When the blind is unwound in front of a window on the first floor of a dwelling, its surface is positioned vertically and an observer placed below will see only the white image bands, therefore the surface of the overall white blind, whereas the solar radiation which comes mainly from above will pass right through the plate and will activate the photovoltaic effect of the collector.

The production of the electrical current produced by the blind will, for example, be able to charge a battery which will be used to power an electric motor for the automated winding and unwinding of the blind.

This configuration is only a simplified example of the manufacture and visual integration of a photovoltaic blind placed in front of a building window, and which uses the device and method that are the subjects of this invention.

The result of the above is that the invention achieves the aims set. It describes a device that has characteristics that are both mechanical and optical for displaying an image on the surface of the solar collectors, and which does not have the drawbacks of the currently known devices.

The device that is the subject of the invention will make it possible to make the solar collectors flexible enough to be able to give them diverse forms and/or wind them for example around a cylinder while retaining thicknesses compatible with industrial manufacture.

The device that is the subject of the invention will, in addition allow for image viewing angles and solar radiation capture angles over a greater angular range, potentially up to 180° in total.

The invention is particularly suited to the visual integration of the solar collectors in blinds, sun shades, sun roofs, parasols, awnings, roofs, walls, tiles, glazing, transport vehicles, including boats and airplanes, advertising panels and billboards, electronic screens, clothing, and, generally, on any support with images, including electronic images, and on any planar or non-planar surfaces.

1. A device comprising at least one collector of light energy originating from a light source, further including a transparent plate positioned between the light source and said collector, said transparent plate having a first face of which is structured by a network of lenses separated by slots, the distance between the bottom of the slots formed on the first face of the transparent plate and a second, opposite face of the transparent plate being such that it allows the transparent plate to flex, whereas the second face of the transparent plate contains areas of pixels of an image, and areas of transparency.

2. The device as claimed in claim 1, wherein said lenses are convex or concave, and of symmetrical or asymmetrical form.

3. The device as claimed in claim 1, wherein an area of pixels and an area of transparency are situated in a patch of said second face delimited by two consecutive slots.

4. The device as claimed in claim 1, wherein the light source is the sun, and wherein said light energy collector is a solar collector of thermal, photovoltaic or chemical type.

5. The device as claimed in claim 1, wherein the transparent plate is made of glass or of organic glass, or of a transparent polymer of PMMA, PET or polycarbonate type.

6. The device as claimed in claim 1, wherein the transparent plate is colored in its mass.

7. The device as claimed in claim 1, wherein the slots are rectilinear and parallel to one another.

8. The device as claimed in claim 1, wherein the slots are delimited by cylindrical or polygonal forms, or by optical fibers.

9. The device as claimed in claim 1, wherein the slots are perpendicular to the plane of the transparent plate, or inclined by a certain angle relative to a perpendicular relative to the plane of the transparent plate.

10. The device as claimed in claim 1, wherein the slots are formed on said first face exposed to light and/or on said second face of the transparent plate.

11. The device as claimed in claim 1, wherein the distance between the bottom of the slots formed on the first face of the transparent plate and the second, opposite face is small enough to allow for a flexing of the material without breaking.

12. The device as claimed in claim 1, wherein the walls of the slots are smooth and/or polished.

13. The device as claimed in claim 1, wherein the areas of pixels contain printed pixels or electronic pixels generated by backlit, light-emitting or reflecting components.

14. The device as claimed in claim 1, wherein the collector is flexible and/or non-rigid along at least one axis.

15. The device as claimed in claim 1, wherein the device can be wound around an axis or a cylinder which is substantially parallel to the longitudinal axis of the slots.

16. The device as claimed in claim 1, wherein the collector covers all of the surface of one of the faces of the transparent plate, or covers only the areas of transparency, or covers only some of the areas of transparency.

17. The device as claimed in claim 1, wherein the collector is positioned on one of the faces of the slots, and wherein the areas of pixels cover all or part of the face of the transparent plate opposite that which bears the slots.

18. The device as claimed in claim 1, wherein the areas of pixels are wholly or partly transparent to the light.

19. A method for manufacturing a device as claimed in claim 1, comprising:
procuring a transparent plate structured on one of its faces by a network of lenses, and comprising, on the other face, an image formed by areas of pixels, spaced apart by bands of transparency;
depositing a layer of photovoltaic amorphous silicon on the image face,
producing, in the face provided with lenses, between two consecutive lenses, slots with a depth that leaves a thickness of material remaining capable of ensuring that the transparent plate can flex.

20. A method for manufacturing a device as claimed in claim 1, comprising:
procuring transparent rods, one of the faces of which is in the form of a lens, and a transparent film, on one of the faces of which is provided with image areas spaced apart by bands of transparency;
gluing the faces of said transparent rods side by side on said transparent film in such a way that each rod is glued by its face opposite that which is in the form of a lens, and in such a way as to leave, between each of said rods, an air space with parallel faces, said rods having a width such that they cover an image band and a band of transparency;
procuring one or more solar collectors and positioning them on the face of said transparent plate opposite that which bears the slots, so that said solar collectors have their active faces facing the areas of transparency.

21. A method for manufacturing a device as claimed in claim 1, wherein a transparent plate is procured that has a face provided with a network of lenses and a planar face, and wherein a network of lenses separated by slots is formed on one of the two faces, by molding, thermoforming or extrusion.
